(19) United States
(12) Patent Application Publication
(10) Pub. No.: US 2025/0261390 A1
(43) Pub. Date: Aug. 14, 2025

(54) METHOD OF MANUFACTURING SILICON CARBIDE SEMICONDUCTOR DEVICE

(71) Applicant: FUJI ELECTRIC CO., LTD., Kawasaki-shi (JP)

(72) Inventor: Takahito KOJIMA, Matsumoto-city (JP)

(73) Assignee: FUJI ELECTRIC CO., LTD., Kawasaki-shi (JP)

(21) Appl. No.: 19/005,776

(22) Filed: Dec. 30, 2024

(30) Foreign Application Priority Data
Feb. 9, 2024 (JP) 2024-019027

(51) Int. Cl. H10D 30/01; H01L 21/04

(52) U.S. Cl. CPC H10D 30/0297; H01L 21/046

(57) ABSTRACT

A method of manufacturing a silicon carbide semiconductor device includes: preparing a silicon carbide semiconductor substrate including a first semiconductor layer of a first conductivity type disposed on a front surface of a starting substrate of the first conductivity type, the first semiconductor layer having a dopant concentration lower than a dopant concentration of the starting substrate; forming semiconductor regions of the first conductivity type and of a second conductivity type in the first semiconductor layer by ion implantation; forming trenches in the silicon carbide semiconductor substrate, at a front surface thereof; forming a carbon film on the front surface of the silicon carbide semiconductor substrate; performing a cycle purge of the silicon carbide semiconductor substrate by alternatingly pressurizing the silicon carbide semiconductor substrate with a purge gas and venting the purge gas in a chamber; removing the silicon carbide semiconductor substrate from the chamber; and activating the semiconductor regions formed by the ion implantation.

### CROSS REFERENCE TO RELATED APPLICATIONS

This application is based upon and claims the benefit of priority of the prior Japanese Patent Application No. 2024-019027, filed on Feb. 9, 2024, the entire contents of which are incorporated herein by reference.

### BACKGROUND OF THE INVENTION

### 1. Field of the Invention

Embodiments of the invention relate to a method of manufacturing a silicon carbide semiconductor device.

### 2. Description of the Related Art

According to a known technique, a protective film is deposited in the form of a diamond-like carbon film or an organic film on a surface and is then annealed (for example, refer to Japanese Patent No. 3760688). According to another known technique, a substrate is maintained under an atmospheric state until thermal expansion of the substrate is saturated, then the inside of a furnace body is evacuated, and a gas, which is a raw material for film formation, is supplied into the furnace body, whereby a thin film is formed on a surface of the substrate by a chemical reaction (for example, refer to Japanese Laid-Open Patent Publication No. 2005-85794).

### SUMMARY OF THE INVENTION

According to an embodiment of the present disclosure, a method of manufacturing a silicon carbide semiconductor device, the method includes: as a first process, preparing a silicon carbide semiconductor substrate including: a starting substrate of a first conductivity type, and a first semiconductor layer of the first conductivity type, provided on a front surface of the starting substrate, the first semiconductor layer having a dopant concentration lower than a dopant concentration of the starting substrate; as a second process, forming a plurality of semiconductor regions of the first conductivity type and of a second conductivity type in the first semiconductor layer by ion implantation; as a third process, forming a plurality of trenches in the silicon carbide semiconductor substrate, at a surface of the silicon carbide semiconductor substrate; as a fourth process, forming a carbon film on the surface of the silicon carbide semiconductor substrate; as a fifth process, performing a cycle purge of the silicon carbide semiconductor substrate by alternatingly pressurizing the silicon carbide semiconductor substrate with a purge gas and venting the purge gas in a cycle purge chamber; as a sixth process, removing the silicon carbide semiconductor substrate from the cycle purge chamber; and as a seventh process, activating the plurality of semiconductor regions formed by the ion implantation.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a configuration of a silicon carbide semiconductor device according to an embodiment.

FIG. 2 is a cross-sectional view schematically depicting a state of the silicon carbide semiconductor device according to the embodiment during manufacturing.

FIG. 3 is a cross-sectional view schematically depicting a state of the silicon carbide semiconductor device according to the embodiment during manufacturing.

FIG. 4 is a cross-sectional view schematically depicting a state of the silicon carbide semiconductor device according to the embodiment during manufacturing.

FIG. 5 is a cross-sectional view schematically depicting a state of the silicon carbide semiconductor device according to the embodiment during manufacturing.

FIG. 6 is a cross-sectional view schematically depicting a state of the silicon carbide semiconductor device according to the embodiment during manufacturing.

FIG. 7 is a cross-sectional view schematically depicting a state of the silicon carbide semiconductor device according to the embodiment during manufacturing.

FIG. 8 is a cross-sectional view schematically depicting a state of the silicon carbide semiconductor device according to the embodiment during manufacturing.

FIG. 9 is a cross-sectional view schematically depicting a state of the silicon carbide semiconductor device according to the embodiment during manufacturing.

FIG. 10 is a flowchart depicting a method of manufacturing the silicon carbide semiconductor device according to the embodiment.

FIG. 11 is a schematic diagram of a sputtering device used in the method of manufacturing the silicon carbide semiconductor device according to the embodiment.

### DETAILED DESCRIPTION OF THE INVENTION

First, problems associated with the conventional techniques are discussed. In a conventional method of manufacturing a silicon carbide semiconductor device, a problem arises in that when sputtering with plasma discharge is performed with respect to a silicon carbide (SiC) wafer, the SiC wafer is damaged and defects occur.

An outline of an embodiment according to the present disclosure is described. A method of manufacturing a silicon carbide semiconductor device according to the disclosure has the following features. First, a first process is performed of preparing a silicon carbide semiconductor substrate in which a first semiconductor layer of a first conductivity type and having a dopant concentration lower than a dopant concentration of a starting substrate is provided on a front surface of the starting substrate. Thereafter, a second process is performed of forming semiconductor regions of a first conductivity type and a second conductivity type in the first semiconductor layer by ion implantation. Next, a third process is performed of forming trenches in the silicon carbide semiconductor substrate, at the front surface thereof. Next, a fourth process is performed of forming a carbon film on the front surface of the silicon carbide semiconductor substrate. Thereafter, a fifth process is performed of cycle purging the silicon carbide semiconductor substrate. Next, a sixth process is performed of removing the silicon carbide semiconductor substrate. Next, a seventh process is performed of activating the semiconductor regions formed by the ion implantation.

According to the above disclosure, after the carbon film is deposited, a cycle purge is performed to discharge unstable foreign matter accumulated in a target and/or chamber. Thus, the amount of foreign matter in the chamber is reduced thereby preventing the foreign matter from adhering to a SiC wafer. Thus, abnormal discharge during plasma ignition is suppressed, whereby chipping of sidewalls of the trenches may be prevented, thereby improving yield.

In the method of manufacturing the silicon carbide semiconductor device according to the disclosure, the cycle purge is performed in the fifth process while the silicon carbide semiconductor substrate is left in a film formation chamber.

According to the disclosure described above, during the cycle purge, unstable foreign matter accumulated in the target and/or chamber may be removed.

In the method of manufacturing the silicon carbide semiconductor device according to the disclosure, in the disclosure above, Ar gas or N₂ gas is used in the fifth process.

In the method of manufacturing the silicon carbide semiconductor device according to the disclosure, in the disclosure above, a gas is introduced from a sputtering gas inlet, in the fifth process.

According to the above disclosure, the introduced gas can remove the unstable foreign matter accumulated in the target and/or chamber.

In the method of manufacturing the silicon carbide semiconductor device according to the disclosure, in the above disclosure, a gas flow rate in the fifth process is greater than a gas flow rate in the fourth process.

In the method of manufacturing the silicon carbide semiconductor device according to the disclosure, in the above disclosure, the cycle purge is performed multiple times in the fifth process.

In the method of manufacturing the silicon carbide semiconductor device according to the disclosure, in the above disclosure, the silicon carbide semiconductor device is an FET, an IGBT, or a diode.

Findings underlying the present disclosure are discussed. First, problems of the conventional manufacturing methods of a silicon carbide semiconductor device are described. Silicon carbide (SiC) is expected to be a next-generation semiconductor material to replace silicon (Si). A semiconductor device that uses silicon carbide as a semiconductor material (hereinafter referred to as silicon carbide semiconductor device) has various advantages as compared to conventional semiconductor devices that use silicon as a semiconductor material, such as an ability to reduce resistance of the device in an on-state to several one-hundredths and an ability to be used under higher temperature environments (200 degrees C. or higher). This is due to characteristics of the material itself in that a band gap of silicon carbide is about three times larger than a band gap of silicon, and a dielectric breakdown field strength of silicon carbide is nearly one order of magnitude larger than a dielectric breakdown field strength of silicon.

As for silicon carbide semiconductor devices, Schottky barrier diodes (SBDs) and vertical metal oxide semiconductor field effect transistors (MOSFETs) with planar gate or trench gate structures have been commercialized so far.

SiC has a problem in that diffusion coefficients of dopants in SiC are extremely small. In an instance in which a dopant layer is formed by ion implantation, formation of the dopant layer deep in the depth direction is difficult. In an instance in which a structure is formed in a vertical direction of a substrate, such as a vertical MOSFET with a trench gate structure, the dopant layer is formed by combining ion implantation and epitaxial growth.

However, the epitaxial growth may cause substrate defects, whereby characteristics of the semiconductor device degrade. Epitaxial growth equipment requires costs for controlling processes and maintaining the equipment. Therefore, development is also advancing with respect to silicon carbide semiconductor devices in which epitaxial growth is not performed and normal energy ion implantation (up to 900 KeV) is combined with high acceleration ion implantation (acceleration energy of 1 MeV or more) capable of deeper dopant implantation, whereby the dopant layer is formed by only ion implantation.

In the manufacture of semiconductor devices, high temperatures of 1500 degrees C. or higher are required for activation annealing of the dopants implanted in the SiC. When the high-temperature annealing is performed, the Si on the SiC surface is vaporized, causing surface roughness. Therefore, surface roughness is suppressed by forming a protective film, such as a carbon film, on the surface to be activated. Regarding the manufacturing process of a vertical SiC-MOSFET having a trench gate structure, one model performs annealing to activate dopants after trenches are formed. The annealing is performed under an argon (Ar) atmosphere at a high temperature of 1600 degrees C. or higher. Since the annealing is after the formation of the trenches, which are about 1 μm deep, unevenness occurs and thus for even deposition, a carbon film of about 250 nm has to be deposited.

While a physical vapor deposition (PVD) method is useful for depositing carbon films, which have a relatively high adhesion, carbon has a characteristic in that fewer atoms are sputtered by plasma as compared to metals. Therefore, from the perspective of productivity, radio frequency (RF) output has to be increased as much as possible to shorten processing time.

Table 1 depicts a sequence of carbon film sputtering in a conventional process. The conventional process is performed in a single step in which, for example, a SiC wafer is placed on a stage in a chamber of a sputtering device; a carbon film is deposited for 15 minutes at a pressure of 0.5 Pa, an Ar flow rate of 60 sccm, and an RF power of 1500 W; and then the wafer is unloaded from the chamber of the sputtering device.

TABLE 1

| | Step1 | |
|---|---|---|
| PRESSURE (Pa) | 0.5 | 0 |
| Ar FLOW RATE (sccm) | 60 | 0 |
| RF POWER (W) | 1500 | 0 |
| TIME | 15 min | UNLOAD |

While plasma discharge is performed in a sputtering method, generally in an instance in which a plasma state is created, the most unstable state occurs when the plasma is ignited. In particular, when foreign matter or the like is attached to the SiC wafer and high output power is used upon plasma ignition, a problem arises in that abnormal discharge originating from the foreign matter easily occurs, causing damage to the SiC wafer and forming defects. Sources of the foreign matter are deposits on a target and/or in the chamber. When the plasma with high output power hits the deposits, which are in an unstable state, the deposits become foreign matter and adhere to the SiC wafer.

Such defects are significant in an instance in which the trenches (grooves) are formed on the SiC wafer, and when the abnormal discharge occurs, a part of the sidewalls of the trenches (groove) becomes chipped. It is presumed that, when foreign matter adheres in a vicinity of a trench sidewall, the trench sidewall is damaged by the abnormal discharge upon the plasma ignition, which causes a part of the trench sidewall to chip.

The present disclosure provides a method of manufacturing a silicon carbide semiconductor device, the method reduces foreign matter generated during sputtering, suppresses abnormal discharge originating from foreign matter generated during plasma ignition, and suppresses damage and defects on a SiC wafer.

An embodiment of a method of manufacturing a silicon carbide semiconductor device according to the present disclosure is described in detail below with reference to accompanying drawings. In the description and the accompanying drawings, a layer or region prefixed with n or p respectively means electrons or holes are majority carriers. Additionally, + or − attached to n or p respectively means that the dopant concentration thereof is higher and lower, respectively, than that of a layer or region not prefixed without + or −. In the description of the embodiments below and the accompanying drawings, main portions that are identical are given the same reference numerals and are not repeatedly described. In the specification, in a notation of Miller indices, “−” means a bar attached to the index immediately following the “−”, and a negative index is represented by adding “−” before the index. Further, with consideration of variation in manufacturing, description indicating the same or equal may be within 5%.

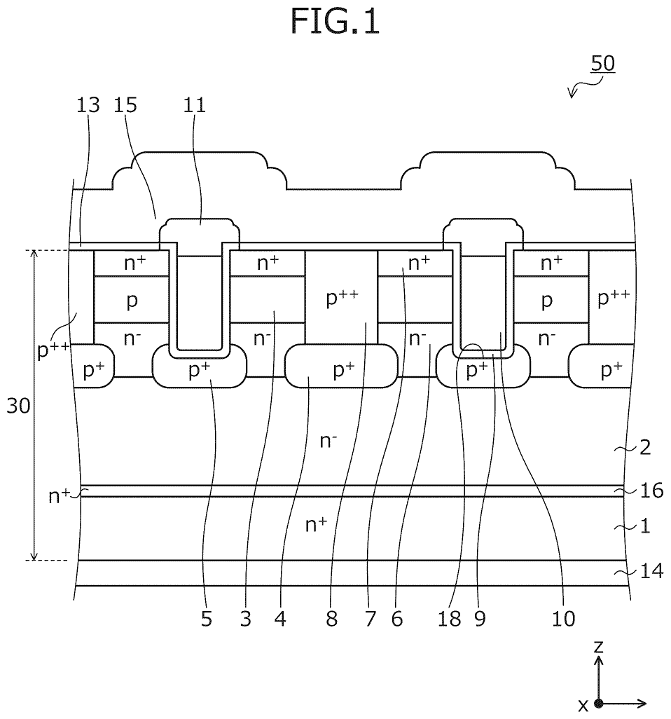

A semiconductor device according to the present disclosure is configured using a wide band gap semiconductor. In the embodiment, the silicon carbide semiconductor device fabricated (manufactured) using, for example, silicon carbide (SIC) as the wide band gap semiconductor is described using a trench-type SiC-MOSFET 50 as an example. FIG. 1 is a cross-sectional view depicting a configuration of the silicon carbide semiconductor device according to the embodiment. In FIG. 1, only an active region through which a main current of the trench MOSFET 50 flows is depicted.

As depicted in FIG. 1, in the silicon carbide semiconductor device according to the embodiment, an n⁺-type buffer layer 16 and a first n⁻-type silicon carbide epitaxial layer 2 are deposited on a first main surface (a front surface) of an n⁺-type starting substrate 1, the first main surface being, for example, a (0001) plane (a Si-face).

The n⁺-type starting substrate 1 is, for example, a silicon carbide single crystal substrate doped with nitrogen (N). The n⁺-type buffer layer 16 is, for example, a highly doped layer doped with nitrogen and having a thickness in a range of 1 μm to 5 μm and a high concentration of nitrogen in a range of 1×10¹⁷/cm³ to 1×10¹⁸/cm³. The n⁺-type buffer layer 16 promotes recombination of holes from the first n⁻-type silicon carbide epitaxial layer 2, controls concentration of holes reaching the n⁺-type starting substrate 1, and suppresses the occurrence and expansion of stacking faults.

The first n⁻-type silicon carbide epitaxial layer 2 is a low-concentration n⁻-type drift layer doped with, for example, nitrogen and having a dopant concentration lower than the dopant concentration of the n⁺-type starting substrate 1. A second n⁻-type silicon carbide layer 6 is formed on a first surface of the first n⁻-type silicon carbide epitaxial layer 2, the first surface being opposite to a second surface thereof facing the n⁺-type starting substrate 1. The second n⁻-type silicon carbide layer 6 is a high-concentration n-type drift layer doped with, for example, nitrogen, and having a dopant concentration lower than the dopant concentration of the n⁺-type starting substrate 1 and higher than that of the first n⁻-type silicon carbide epitaxial layer 2. Hereinafter, the n⁺-type starting substrate 1, the n⁻-type silicon carbide epitaxial layer 2, the second n⁻-type silicon carbide layer 6, and a p-type base layer 3 described later are collectively referred to as a silicon carbide semiconductor substrate.

A back electrode (a drain electrode) is provided on a second main surface (the back surface, i.e., the back surface of the silicon carbide semiconductor substrate) of the n⁺-type starting substrate 1. The back electrode constitutes the drain electrode. A drain electrode pad 14 is provided on the surface of the back electrode.

The trench gate structure is formed in the silicon carbide semiconductor substrate, at a first main surface thereof (surface having the p-type base layer 3). Specifically, trenches 18 penetrate through the p-type base layer 3 from a first surface of the p-type base layer 3, the first surface being opposite to a second surface thereof facing the n⁺-type starting substrate 1; the trenches 18 reach the second n⁻-type silicon carbide layer 6. Along an inner wall of each of the trenches 18, a gate insulating film 9 is formed along a bottom and sidewalls of said trench 18; a gate electrode 10 is formed in each of the trenches 18, on the gate insulating film 9. The gate insulating film 9 insulates the gate electrode 10 from the first n⁻-type silicon carbide epitaxial layer 2, the second n⁻-type silicon carbide layer 6, and the p-type base layer 3. A portion of the gate electrode 10 may protrude from a top (side facing a source electrode pad 15) of said trench 18 in a direction toward the source electrode pad 15.

First p⁺-type regions 4 and second p⁺-type regions 5 are selectively provided in the first n⁻-type silicon carbide epitaxial layer 2 and the second n⁻-type silicon carbide layer 6. The first p⁺-type regions 4 reach a depth closer to the n⁺-type starting substrate 1 than are the bottoms of the trenches 18. Each of the first p⁺-type regions 4 has a lower end (end facing the n⁺-type starting substrate 1) disposed closer to the n⁺-type starting substrate 1 than are the bottoms of the trenches 18. The first p⁺-type regions 4 are provided between the trenches 18. In FIG. 1, while the first p⁺-type regions 4 are depicted to be in contact with p⁺⁺-type contact regions 8 described later, configuration may be such that the first p⁺-type regions 4 are apart from the p⁺⁺-type contact regions 8. In this case, an upper surface of each of the first p⁺-type regions 4 is provided in a surface layer of the second n⁻-type silicon carbide layer 6 and is in contact with a lower surface of the p-type base layer 3.

Each of the second p⁺-type regions 5 has a lower end disposed closer to the n⁺-type starting substrate 1 than are the bottoms of the trenches 18. The second p⁺-type regions 5 are formed at positions facing the bottoms of the trenches 18 in a depth direction z. A width of each of the second p⁺-type regions 5 is wider than a width of each of the trenches 18. The bottoms of the trenches 18 may reach the second p⁺-type regions 5 or may be disposed in the second n⁻-type silicon carbide layer 6, sandwiched between the p-type base layer 3 and the second p⁺-type regions 5 but not in contact with the second p⁺-type regions 5. An upper surface of each of the second p⁺-type regions 5 may be closer to the n⁺-type starting substrate 1 than are the bottoms of the trenches 18, or may be closer to the source electrode pad 15 than are the bottoms of the trenches 18. The first p⁺-type regions 4 and the second p⁺-type regions 5 are doped with, for example, aluminum (Al).

A portion of each of the first p⁺-type regions 4 extends toward the trenches 18, thereby forming a structure in which the first p⁺-type regions 4 are connected to the second p⁺-type regions 5. In this case, said portions of the first p⁺-type regions 4 may have, in a plan view, a layout in which said portions repeatedly alternate with portions of the second n⁻-type silicon carbide layer 6 in a direction (hereinafter referred to as a second direction) y orthogonal to a direction (hereinafter referred to as a first direction) x in which the first p⁺-type regions 4 and the second p⁺-type regions 5 are arranged. That is, the first p⁺-type regions 4 and the second p⁺-type regions 5 suffice to be at least partially connected at one or more locations in the direction y. Thus, holes generated when avalanche breakdown occurs at a junction between the second p⁺-type regions 5 and the first n⁻-type silicon carbide epitaxial layer 2 may be efficiently migrated to source electrodes 13, thereby reducing the load on the gate insulating film 9 and improving reliability.

The p-type base layer 3 is provided on the first surface of the first n⁻-type silicon carbide epitaxial layer 2. A dopant concentration of the p-type base layer 3 may be, for example, lower than a dopant concentration of the first p⁺-type regions 4. Thus, even when the concentration of the p-type base layer 3 is reduced in order to lower the threshold voltage, decreases in the breakdown voltage due to punch-through may be avoided by suppressing the spreading of a depletion layer in the p-type base layer 3. In the p-type base layer 3, at the first surface thereof, n⁺-type source regions 7 and the p⁺⁺-type contact regions 8 are selectively provided. The n⁺-type source regions 7 and the p⁺⁺-type contact regions 8 are in contact with each other.

While only two trench MOS structures are depicted in FIG. 1, more trench-structured MOS gate (metal-oxide-semiconductor insulated gate) structures may be arranged in parallel.

An interlayer insulating film 11 is provided in an entire area of the first main surface of the silicon carbide semiconductor substrate so as to cover the gate electrodes 10 embedded in the trenches 18. The source electrodes 13 are in contact with the n⁺-type source regions 7 and the p⁺⁺-type contact regions 8 via contact holes opened in the interlayer insulating film 11. The source electrodes 13 are electrically insulated from the gate electrodes 10 by the interlayer insulating film 11. The source electrode pad 15 is provided on the source electrodes 13.

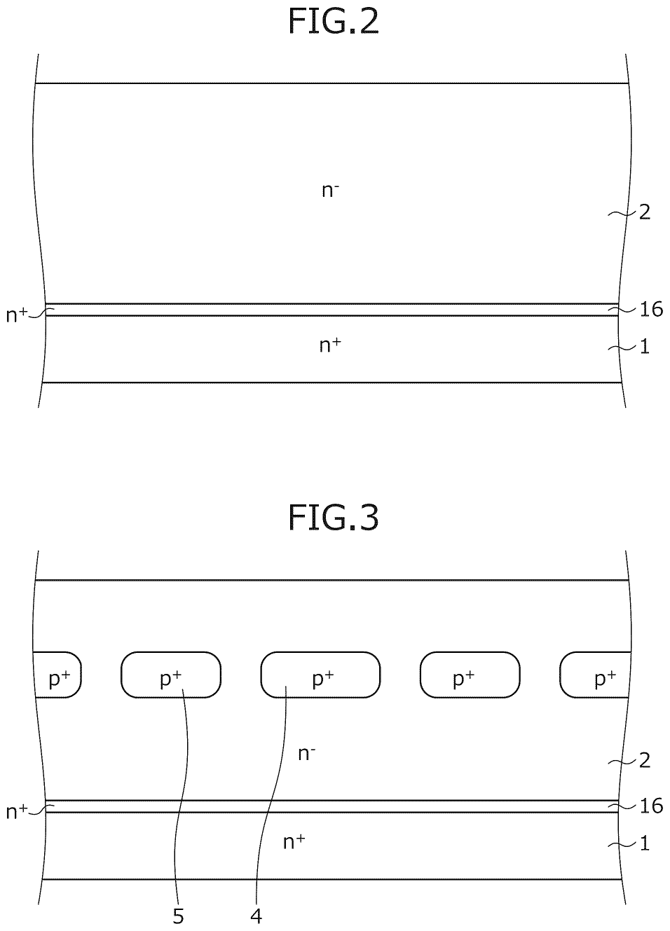

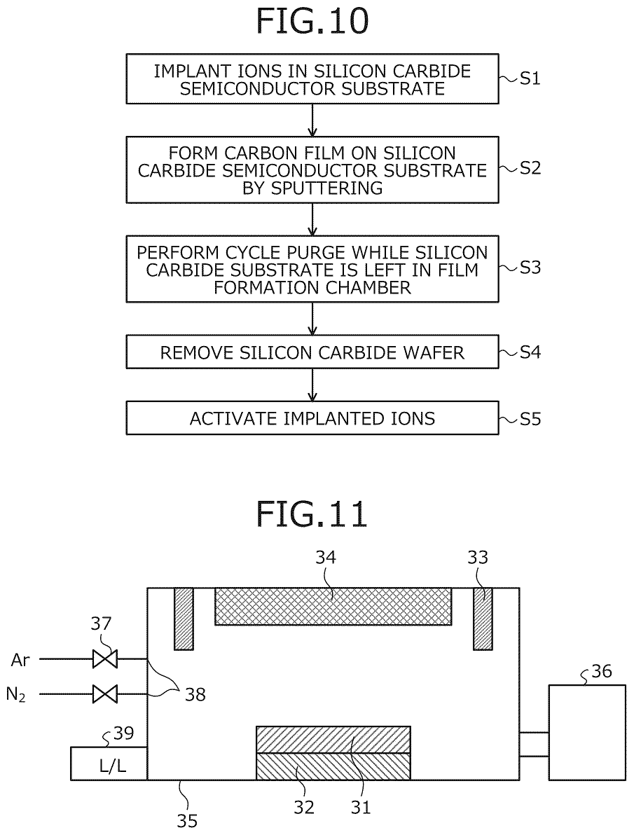

Next, a method of manufacturing a silicon carbide semiconductor device according to the embodiment is described. FIGS. 2, 3, 4, 5, 6, 7, 8, and 9 are cross-sectional views schematically depicting states of the silicon carbide semiconductor device according to the embodiment during manufacturing. FIG. 10 is a flowchart depicting the method of manufacturing the silicon carbide semiconductor device according to the embodiment.

First, as depicted in FIG. 2, a silicon carbide semiconductor substrate (wafer) 30 is prepared in which the first n⁻-type silicon carbide epitaxial layer (first semiconductor layer of a first conductivity type) 2 and an n⁺-type buffer layer 16 are deposited on the n⁺-type starting substrate (starting substrate of the first conductivity type) 1 containing an n-type silicon carbide (first process). A diameter of the n⁺-type starting substrate (wafer) used here is 150 mm. The silicon carbide semiconductor substrate 30 may be purchased, or a substrate consisting of only the n⁺-type starting substrate 1 may be purchased and the n⁺-type buffer layer 16 and the first n⁻-type silicon carbide epitaxial layer 2 may formed thereon by epitaxy, thereby obtaining the silicon carbide semiconductor substrate 30. In this case, the n⁺-type buffer layer 16, which contains silicon carbide, is grown on the first main surface of the n⁺-type starting substrate 1 by epitaxy while an n-type dopant, for example, nitrogen atoms (N), is doped. Thereafter, the first n⁻-type silicon carbide epitaxial layer 2 containing silicon carbide is grown on the n⁺-type buffer layer 16 while an n-type dopant, for example, nitrogen atoms, is doped.

Next, a resist mask (not depicted) having predetermined openings is formed on the surface of the first n⁻-type silicon carbide epitaxial layer 2 by photolithography. Then, as depicted in FIG. 3, a p-type dopant, for example, aluminum atoms, is implanted by an ion implantation method, thereby forming the first p⁺-type regions 4 and the second p⁺-type regions 5 in the first n⁻-type silicon carbide epitaxial layer 2, the first p⁺-type regions 4 and the second p⁺-type regions 5 having a depth of about 0.6 μm and a dopant concentration of, for example, 3×10¹⁸/cm³.

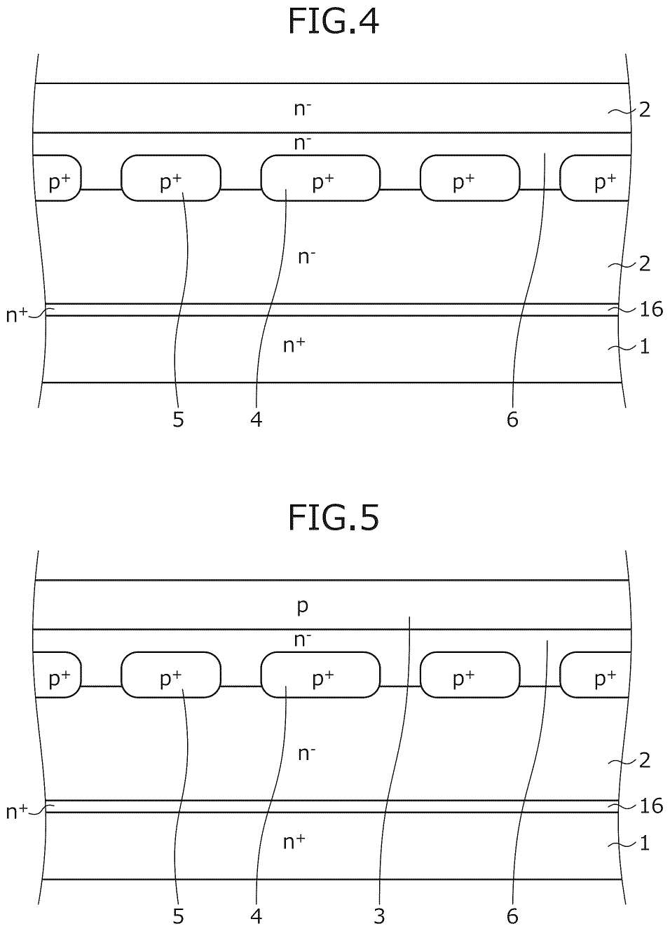

Thereafter, a resist mask (not depicted) having predetermined openings is formed on the surface of the first n⁻-type silicon carbide epitaxial layer 2 by photolithography. Then, as depicted in FIG. 4, the second n⁻-type silicon carbide layer 6, which has a thickness of about 0.7 μm, is formed; the second n⁻-type silicon carbide layer 6 is doped with an n-type dopant such as nitrogen by ion implantation and has a dopant concentration of, for example, 2×10¹⁷/cm³.

Next, a resist mask (not depicted) having a predetermined opening is formed on the surface of the n⁻-type silicon carbide epitaxial layer 2 by photolithography. Then, as depicted in FIG. 5, a p-type dopant is ion-implanted into the n⁻-type silicon carbide epitaxial layer 2. Thus, the p-type base layer 3 having a thickness of about 0.5 μm and a dopant concentration of, for example, 3×10¹⁷/cm³ is formed.

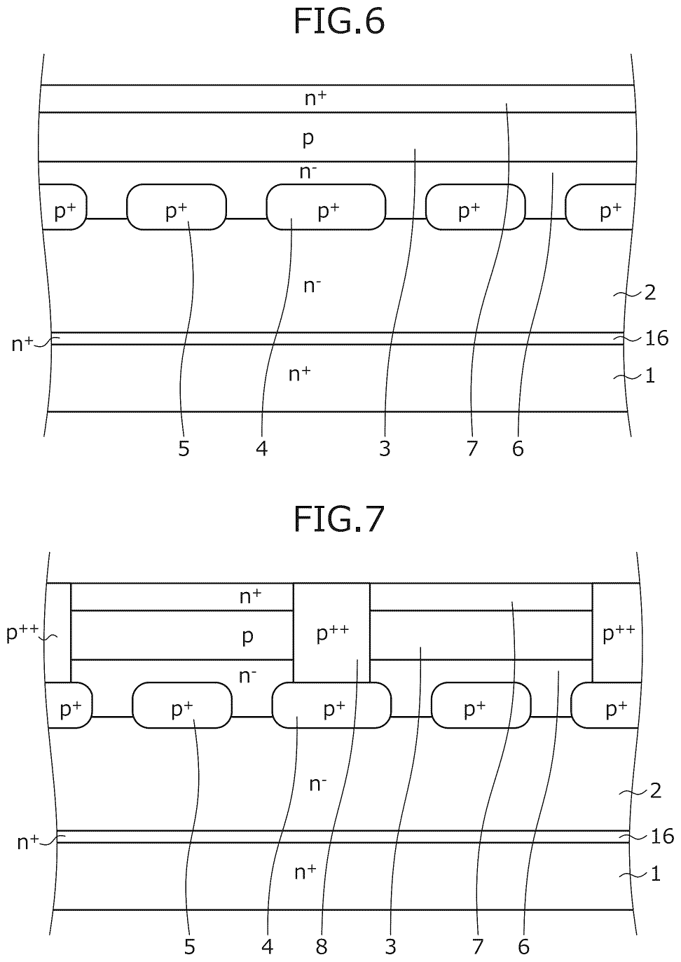

Thereafter, a resist mask (not depicted) having a predetermined opening is formed on the surface of the p-type base layer 3 by photolithography. Then, as depicted in FIG. 6, an n-type dopant is ion-implanted into a portion of the n⁻-type silicon carbide epitaxial layer 2. Thus, an n⁺-type source layer 7 having a thickness of about 0.5 μm and a dopant concentration of, for example, 1×10¹⁹/cm³ is formed.

Next, an ion implantation mask having predetermined openings is formed and a p-type dopant such as aluminum is ion-implanted into portions of the n⁺-type source layer 7 and portions of the p-type base layer 3. Thus, as depicted in FIG. 7, the p⁺⁺-type contact regions 8 having a dopant concentration of, for example, 1×10²⁰/cm³ are formed.

As described, a p-type dopant is ion-implanted into the n⁻-type silicon carbide epitaxial layer 2 of the silicon carbide semiconductor substrate 30, thereby forming p-type semiconductor regions (the p-type base layer 3, the first p⁺-type regions 4, the second p⁺-type regions 5, and p⁺⁺-type contact regions 8). An n⁻-type dopant is ion-implanted, thereby forming n-type semiconductor regions (the second n⁻-type silicon carbide layer 6 and the n⁺-type source regions 7) (step S1: second process).

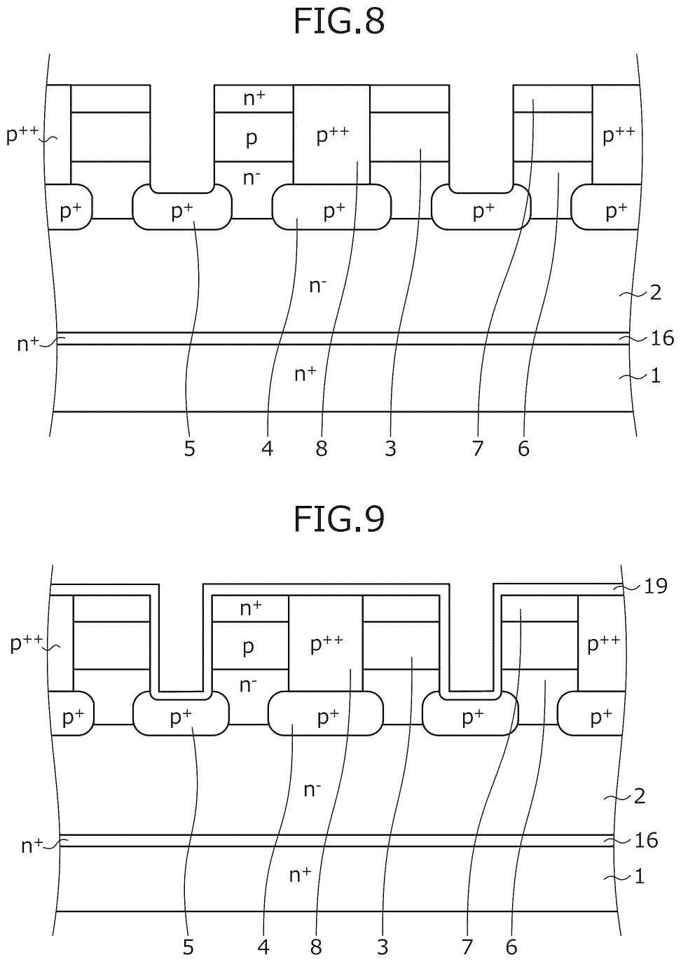

Thereafter, a mask for forming the trenches and having predetermined openings is formed on the surface of the n⁺-type source regions 7 by photolithography, using, for example, an oxide film. Next, as depicted in FIG. 8, the trenches 18, which penetrate through the n⁺-type source regions 7 and the p-type base layer 3 and reach the second p⁺-type regions 5, are formed by dry etching (third process). Next, the mask for forming trenches is removed. Here, while the trenches 18 are formed after the n⁺-type source regions 7 and the p⁺⁺-type contact regions 8 are formed, the n⁺-type source regions 7 and the p⁺⁺-type contact regions 8 may be formed after the trenches 18 are formed.

Thereafter, as depicted in FIG. 9, a carbon film 19 is formed on the surface of the silicon carbide semiconductor substrate 30 by sputtering (step S2: fourth process). In the embodiment, the trenches 18 are formed, and to enable even deposition on the surface of the trenches 18, a carbon film of about 250 nm is deposited.

FIG. 11 is a schematic diagram of a sputtering device used in the method of manufacturing the silicon carbide semiconductor device according to the embodiment. As the sputtering device, a single-wafer type device that processes semiconductor wafers one by one is depicted. In the sputtering device, a SiC wafer 31 is placed on a stage 32 in a chamber (film formation chamber) 35, and Ar ions or N₂ ions are collided with a carbon (C) target 34 under plasma discharge, and a target material knocked out by the collision is attached to the facing SiC wafer 31. The sputtering device has such as an adhesion prevention plate 33, a valve 37 that controls injection of a sputtering gas such as Ar gas or N₂ gas, an exhaust system 36 for exhausting the sputtering gas, a sputtering gas inlet 38, and an automatic transport load lock (L/L) chamber 39. The SiC wafer 31 is the silicon carbide semiconductor substrate 30 in which the p-type and n-type semiconductor regions and trenches 18 are formed.

Here, in the embodiment, a cycle purge is performed while the SiC wafer 31 is left in the film formation chamber (step S3: fifth process). In the cycle purge, after sputtering, in a state where no plasma is generated, pressurization which introduces an inert gas such as Ar gas or N₂ gas into the chamber from the sputtering gas inlet 38, and evacuation which exhausts the inert gas such as Ar gas or N₂ gas from the exhaust system 36 are performed multiple times. This time, the pressurization and evacuation are performed as one set, several times. By introducing an inert gas such as Ar gas or N₂ gas from the sputtering gas inlet 38, the introduced inert gas can remove unstable foreign matter accumulated in the target and/or chamber. A gas flow rate of the inert gas in the cycle purge is preferably greater than the gas flow rate when the carbon film is formed. In addition, the pressure of the pressurization in the cycle purge is preferably greater than the pressure when the carbon film is formed.

Table 2 depicts a sequence of carbon film sputtering in a process according to the embodiment. The process according to the embodiment is performed in multiple steps including, for example, loading the SiC wafer 31 to the stage 32 in the chamber 35 of the sputtering device and depositing the carbon film for 15 minutes with a pressure of 0.5 Pa, an Ar flow rate of 60 sccm, and an RF power of 1500 W, as step 1; thereafter evacuating the chamber 35 for about 5 seconds as step S2; applying pressure of 100 Pa with an Ar flow rate of 1000 sccm for about 5 seconds as step S3; repeating steps 2 and 3 one or more times; and then unloading the SiC wafer 31 from the chamber of the sputtering device.

TABLE 2

| | | Step2 | Step3 | | |
|---|---|---|---|---|---|
| | | (EVACUA- | (PRESSUR- | | |
| | Step1 | TION) | IZATION) | . . . | |
| PRESSURE (Pa) | 0.5 | 0 | 100 | . . . | 0 |
| Ar FLOW RATE | 60 | 0 | 1000 | . . . | 0 |
| (sccm) | | | | | |
| RF POWER (W) | 1500 | 0 | 0 | . . . | 0 |
| TIME | 15 min | 5 sec | 5 sec | . . . | UNLOAD |

Values in Table 2 are examples, and in step 1 of depositing the carbon film, preferably, the pressure may be in a range of 0.1 Pa to 1.0 Pa, the Ar flow rate may be in a range of 10 sccm to 100 sccm, the RF power may be in a range of 1000 W to 2000 W, and the time may be in a range of 10 minutes to 20 minutes. Further, in step 2 of evacuating the chamber 35, preferably, the time may be in a range of 4 seconds to 60 seconds. Further, in step 3 of applying pressure, preferably, the pressure may be 50 Pa or higher, the Ar flow rate may be 500 sccm or higher, and the time may be in a range of 4 seconds to 60 seconds. Although, Ar is depicted as an example here, the values are the same for N₂ and other inert gases.

As described, the cycle purge is performed, so that unstable foreign matter accumulated in the target and/or chamber can be discharged. During the cycle purge, the SiC wafer 31 in the chamber may be collected or left therein; this time, the cycle purge was performed with the SiC wafer 31 left in the stage 32. Thereafter, the SiC wafer 31 is removed (step S4: sixth process). The SiC wafer 31 is placed in the stage 32, whereby the foreign matter on the SiC wafer 31 may be removed during the cycle purge.

The cycle purge is performed, whereby the foreign matter in the chamber is reduced, thereby suppressing adhesion of foreign matter to the SiC wafer. Thus, abnormal discharge during plasma ignition is suppressed, thereby preventing chipping of portions of trench sidewalls and thus, improving yield. The trenches here are not limited to the trenches 18 that function as gate trenches and include all grooves provided on the front surface of the silicon carbide semiconductor substrate 30.

Next, a heat treatment is performed under an inert gas atmosphere at a temperature of about 1750 degrees C., thereby implementing an activation process of a dopant regions formed by ion implantation (step S5: seventh process).

Thereafter, the gate insulating film 9 is formed along the surfaces of the n⁺-type source regions 7 and the p⁺⁺-type contact regions 8, and the bottoms and sidewalls of the trenches 18. The gate insulating film 9 may be formed by thermal oxidation at a temperature of about 1300 degrees C. under a gas atmosphere containing oxygen. The gate insulating film 9 may also be formed by a method of deposition by a chemical reaction such as high temperature oxidation (HTO).

Next, a polycrystalline silicon layer doped with, for example, phosphorus atoms, is provided on the gate insulating film 9. The polycrystalline silicon layer may be formed so as to be embedded in the trenches 18. The polycrystalline silicon layer is patterned by photolithography and left inside the trenches 18, thereby forming the gate electrode 10.

Thereafter, the insulating film is formed on the surfaces of the gate electrodes 10. A thermal oxide film is formed by annealing under an oxygen atmosphere at a temperature of, for example, 1000 degrees C. Next, the surface is protected by a protective film, which is formed by, for example, a photoresist. Then, the insulating film, the gate electrodes, and the gate insulating film formed on the back surface are all removed by dry etching. Next, the protective film formed on the surface is removed in an ashing and stripping process. In this case, stripping was performed by ashing in oxygen plasma and cleaning with SPM.

Thereafter, a film of a phosphate-based glass, for example, is formed to a thickness of about 1 μm so as to cover the gate insulating film 9 and the gate electrodes 10, thereby forming the interlayer insulating film 11. Next, the interlayer insulating film 11 and the gate insulating film 10 are patterned by photolithography, thereby forming contact holes that expose the n⁺-type source regions 7 and the p⁺⁺-type contact regions 8. Next, a conductive film containing, for example, nickel, and constituting the source electrodes 13 is formed in the contact holes and on the interlayer insulating film 11 by, for example, a sputtering method. Thereafter, a heat treatment of about 700 degrees C. is performed thereby selectively reacting the conductive film with the silicon carbide, and then unreacted portions of the conductive film are selectively removed, thereby leaving the source electrodes 13 only in the contact holes, so that the n⁺-type source regions 7 and the p⁺⁺-type contact regions 8 are in contact with the source electrodes 13.

Thereafter, a metal film that constitutes the source electrode pad 15 is formed, for example, by a sputtering method, on the source electrodes 13 and the interlayer insulating film 11 on the front surface of the silicon carbide semiconductor substrate. At this time, a barrier metal (not depicted) containing titanium or titanium nitride may be formed in advance. A portion of an electrode pad is on the interlayer insulating film 11 and, for example, may have a thickness of 5.5 μm. The electrode pad may be formed of, for example, aluminum containing 1% silicon (Al—Si). Next, the metal film is selectively removed to thereby form the source electrode pad 15.

Thereafter, the front surface of the n⁺-type starting substrate 1 is covered and protected by a protective film (not depicted), and then the n⁺-type starting substrate 1 may be polished from the back side, thereby reducing the thickness of the n⁺-type starting substrate 1 to be a product thickness.

Next, conductive films constituting the drain electrode (not depicted), for example, a molybdenum film and a nickel film, are successively deposited on the second main surface of the n⁺-type starting substrate 1 by, for example, a sputtering method. Thereafter, a heat treatment such as laser annealing is performed to cause the n⁺-type starting substrate 1 to react with the conductive films and form an ohmic junction, thereby forming the drain electrode.

Next, as the drain electrode pad 14, for example, titanium, nickel and gold are deposited in this order on the surface of the drain electrode. As described, the silicon carbide semiconductor device depicted in FIG. 1 is completed.

As described above, according to the embodiment, the carbon film is deposited and the cycle purge is then performed to discharge unstable foreign matter accumulated in the target and/or chamber. Thus, the amount of foreign matter in the chamber is reduced to prevent the foreign matter from adhering to the SiC wafer. As a result, abnormal discharge during plasma ignition is suppressed, thereby suppressing chipping of portions of the trench sidewalls to improve yield.

In the foregoing, the disclosure may be modified in various ways within a range not departing from the spirit of the disclosure and in each of the embodiments described above, dimensions, dopant concentrations, etc., of each region are variously set depending on required specifications. In the embodiments, while the first conductivity type is assumed to be an n-type and the second conductivity type is assumed to be a p-type, the present disclosure is similarly implemented when the first conductivity type is a p-type and the second conductivity type is an n-type. While the embodiments are described using a MOSFET, this is not limitative and the present disclosure is further applicable to an IGBT, a FET having a trench structure, and a diode. In the above embodiments, the semiconductor may be a wide band gap semiconductor such as gallium nitride (GaN) or the like in addition to the silicon carbide (SiC).

According to the disclosure above, after the carbon film is deposited, the cycle purge is performed to discharge unstable foreign matter accumulated in a target and/or chamber. Therefore, the amount of foreign matter in the chamber is reduced to thereby prevent the foreign matter from adhering to a SiC wafer. Thus, abnormal discharge during plasma ignition is suppressed, thereby preventing chipping of portions of the trench sidewalls and thus, improving yield.

According to the method of manufacturing a silicon carbide semiconductor device disclosed herein, damage to a SiC wafer caused by plasma discharge may be suppressed.

As described above, the method of manufacturing the silicon carbide semiconductor device according to the present disclosure is useful for high-voltage semiconductor devices used in power converting equipment and power supply devices of various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

1. A method of manufacturing a silicon carbide semiconductor device, the method comprising:
as a first process, preparing a silicon carbide semiconductor substrate including:
a starting substrate of a first conductivity type, and
a first semiconductor layer of the first conductivity type, provided on a front surface of the starting substrate, the first semiconductor layer having a dopant concentration lower than a dopant concentration of the starting substrate;
as a second process, forming a plurality of semiconductor regions of the first conductivity type and of a second conductivity type in the first semiconductor layer by ion implantation;
as a third process, forming a plurality of trenches in the silicon carbide semiconductor substrate, at a surface of the silicon carbide semiconductor substrate;
as a fourth process, forming a carbon film on the surface of the silicon carbide semiconductor substrate;
as a fifth process, performing a cycle purge of the silicon carbide semiconductor substrate by alternatingly pressurizing the silicon carbide semiconductor substrate with a purge gas and venting the purge gas in a cycle purge chamber;
as a sixth process, removing the silicon carbide semiconductor substrate from the cycle purge chamber; and
as a seventh process, activating the plurality of semiconductor regions formed by the ion implantation.

2. The method according to claim 1, wherein the fifth process includes performing the cycle purge with the silicon carbide semiconductor substrate left in a film formation chamber used as the cycle purge chamber in the fourth process.

3. The method according to claim 1, wherein the fifth process includes using an Ar gas or an N₂ gas as the purge gas.

4. The method according to claim 1, wherein the fifth process includes introducing the purge gas from a supply gas inlet.

5. The method according to claim 1, wherein
the fourth process including forming the carbon film by sputtering carbon on the surface of the silicon carbide semiconductor substrate with a sputter gas in a film formation chamber, and
the fifth process includes, using the film formation chamber as the cycle purge chamber to perform the cycle purge, using a flow rate of the purge gas that is greater than a flow rate of the sputter gas in the fourth process.

6. The method according to claim 1, wherein the fifth process includes performing the cycle purge a plurality of times.

7. The method according to claim 1, wherein the silicon carbide semiconductor device is a FET, an IGBT, or a diode.
